(19) United States
(12) Patent Application Publication
(10) Pub. No.: US 2024/0394435 A1
(43) Pub. Date: Nov. 28, 2024

(54) SECURITY SIMULATION SYSTEM AND NON-TRANSITORY COMPUTER-READABLE RECORDING MEDIUM

(71) Applicant: TOYOTA JIDOSHA KABUSHIKI KAISHA, Aichi-ken (JP)

(72) Inventors: Norimasa KOBORI, Tokyo-to (JP); Yumi SATO, Tokyo-to (JP); Bing XUE, Tokyo-to (JP); Takashi HOMMA, Tokyo-to (JP); Sho OTAKI, Kanagawa-ken (JP); Quan KONG, Tokyo-to (JP); Yohei OZAO, Tokyo-to (JP)

(21) Appl. No.: 18/664,295

(22) Filed: May 15, 2024

(30) Foreign Application Priority Data
May 24, 2023 (JP) 2023-085656

(51) Int. Cl. G06F 30/20; G06V 20/52

(52) U.S. Cl. CPC G06F 30/20; G06V 20/52

(57) ABSTRACT

A security system in a predetermined area is based on a cooperation of security guards and moving bodies. A time-dependent position of each moving body is predetermined. A security simulation system performs a simulation of the security system to search for an appropriate time-dependent position of each security guard. The security simulation system calculates a rushing time from when an abnormality is detected by a first moving body to when a first security guard arrives at a position of the first moving body, and calculates a security coverage area that can be monitored by the security guards and the moving bodies. An evaluation function increases as the rushing time becomes shorter and as the security coverage area becomes wider. The security simulation system determines the time-dependent position of each security guard such that a value of the evaluation function becomes a predetermined level or higher.

### CROSS-REFERENCES TO RELATED APPLICATION

The present disclosure claims priority to Japanese Patent Application No. 2023-085656, filed on May 24, 2023, the contents of which application are incorporated herein by reference in their entirety.

### TECHNICAL FIELD

The present disclosure relates to a technique for performing a simulation of a security system.

### BACKGROUND ART

Patent Literature 1 discloses a security planning support method for supporting determination of deployment of lots of security guards in a security area.

### LIST OF RELATED ART

Patent Literature 1: Japanese Laid-Open Patent Application No. JP-2016-149027

### SUMMARY

The following case is conceivable, that is, security in a predetermined area is implemented by a cooperation between one or more security guards and one or more moving bodies other than human. It is desired to search for and examine an appropriate security system in such the case. In the above-described Patent Literature 1, only the security guards exist, and no cooperation between the moving bodies and the security guards is considered.

An object of the present disclosure is to provide a technique capable of searching for an appropriate security system in a case where security is based on a cooperation between one ore more security guards and one or more moving bodies.

A first aspect is directed to a security simulation system for performing a simulation of a security system.

The security system in a predetermined area is based on a cooperation of N security guards (N is an integer of 1 or more) and M moving bodies (M is an integer of 1 or more).

A time-dependent position of each of the N security guards is a variable in the simulation. A time-dependent position of each of the M moving bodies is predetermined.

The security simulation system includes one or more processors.

The one or more processors are configured to:
perform simulations of the N security guards, the M moving bodies, and abnormality occurrence in the predetermined area;
calculate a rushing time from when an abnormality is detected based on a camera mounted on a first moving body to when a first security guard arrives at a position of the first moving body;
calculate a security coverage area that can be monitored by the N security guards and the M moving bodies in a predetermined period of time; and
determine the time-dependent position of each of the N security guards such that a value of an evaluation function becomes equal to or higher than a predetermined level, wherein the evaluation function increases as the rushing time becomes shorter, and the evaluation function increases as the security coverage area becomes wider.

A second aspect is directed to a security simulation program for performing a simulation of a security system.

The security system in a predetermined area is based on a cooperation of N security guards (N is an integer of 1 or more) and M moving bodies (M is an integer of 1 or more).

A time-dependent position of each of the N security guards is a variable in the simulation. A time-dependent position of each of the M moving bodies is predetermined.

The security simulation program is executed by a computer.

The security simulation program causes the computer to execute:
performing simulations of the N security guards, the M moving bodies, and abnormality occurrence in the predetermined area;
calculating a rushing time from when an abnormality is detected based on a camera mounted on a first moving body to when a first security guard arrives at a position of the first moving body;
calculating a security coverage area that can be monitored by the N security guards and the M moving bodies in a predetermined period of time; and
determining the time-dependent position of each of the N security guards such that a value of an evaluation function becomes equal to or higher than a predetermined level, wherein the evaluation function increases as the rushing time becomes shorter, and the evaluation function increases as the security coverage area becomes wider.

According to the present disclosure, the simulation of the security system that is based on the cooperation of one or more security guards and one or more moving bodies is performed. In the simulation, the rushing time and the security coverage area, which are in a trade-off relationship, are taken into consideration. More specifically, the value of the evaluation function, which increases as the rushing time becomes shorter and as the security coverage area becomes wider, is calculated. Moreover, the position of each security guard is determined such that the value of the evaluation function becomes equal to or higher than a predetermined level. In this manner, it is possible to search for and examine an appropriate security system. This also contributes to proper labor costs of the security guards.

### BRIEF DESCRIPTION OF DRAWINGS

FIG. 1 is a conceptual diagram for explaining a security system according to an embodiment;

FIG. 2 is a conceptual diagram for explaining processing at a time of abnormality detection according to an embodiment;

FIG. 3 is a block diagram showing an example of a configuration of a security simulation system according to an embodiment; and

FIG. 4 is a conceptual diagram for explaining a security simulation according to an embodiment.

### DETAILED DESCRIPTION

### 1. Security System

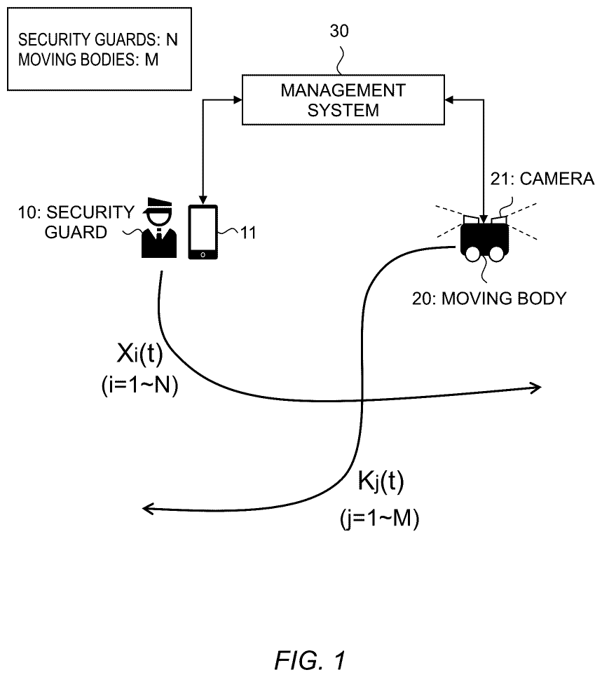

FIG. 1 is a conceptual diagram for explaining a security system which is a premise of the present embodiment. According to the present embodiment, security in a predetermined area is implemented by a cooperation between one or more security guards 10 and one or more moving bodies 20. Examples of the predetermined area include a town, a building, and the like.

The security guard 10 is a human being and monitors the surroundings with his or her eyes. Typically, the security guard 10 carries out the monitoring while moving in the predetermined area. Moreover, the security guard 10 carries a terminal 11. The terminal 11 has a function of acquiring its own position information. For example, the terminal 11 acquires the position information by the use of a global navigation satellite system (GNSS). In addition, the terminal 11 is able to communicate with a management system 30 that manages the security. The terminal 11 may transmit its own position information to the management system 30.

The number of security guards 10 present in the predetermined area is N. Here, N is an integer of 1 or more. In the following description, “i” is an identifier of a security guard 10i and takes a value of 1 to N. Xi(t) represents a position of the security guard 10i and depends on time t. A set of the positions Xi(t) corresponds to a patrol route of the security guard 10i.

On the other hand, the moving body 20 is other than a human being. Examples of the moving body 20 include a vehicle, a robot, a drone, and the like. The moving body 20 may have an autonomous movement function. For example, the moving body 20 is an autonomous driving vehicle. The moving body 20 is able to communicate with the management system 30 that manages security. It should be noted that the moving body 20 does not need to be dedicated to the security. For example, the moving body 20 may be a vehicle that provides a mobility service.

The moving body 20 is equipped with a camera 21 that captures an image of the surrounding situation. The moving body 20 acquires an image captured (taken) by the camera 21. Typically, the moving body 20 recognizes a situation around the moving body 20 based on the acquired image to control the moving body 20. For example, when the moving body 20 is an autonomous driving vehicle, the autonomous driving vehicle performs autonomous driving control based on the image captured by the camera 21 mounted on the autonomous driving vehicle. The moving body 20 may transmit the image to the management system 30.

In addition, the moving body 20 has a function of acquiring its own position information. For example, the moving body 20 acquires the position information by the use of the GNSS. As another example, the moving body 20 may recognize a landmark based on the image captured by the camera 21 and compare the recognized landmark with a landmark registered in map information to estimate its position with high accuracy (this process is called “localization”). The moving body 20 may transmit its own position information to the management system 30.

The image captured by the camera 21 mounted on the moving body 20 is also used for the security in the predetermined area. For example, the moving body 20 detects an abnormality based on the image captured by the camera 21. Examples of the abnormality include an accident, a trouble, a crime, a suspicious person, a sick person, and the like. As another example, the moving body 20 may transmit the image to the management system 30, and the management system 30 may detect the abnormality based on the image. In either case, an abnormality can be detected based on the image by using a machine learning model.

The number of moving bodies 20 present in the predetermined area is M. Here, M is an integer of 1 or more. In the following description, “j” is an identifier of a moving body 20j and takes a value of 1 to M. Kj(t) represents the position of the moving body 20j and depends on the time t. A set of the positions Kj(t) corresponds to a route of the moving body 20j.

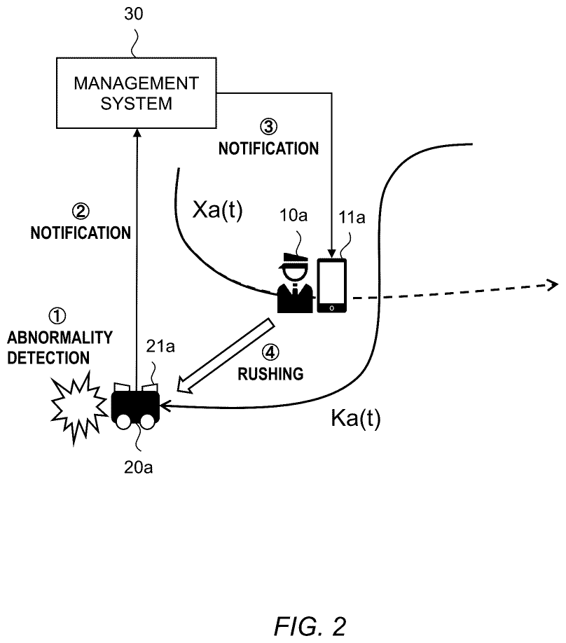

FIG. 2 is a conceptual diagram for explaining processing at a time of the abnormality detection. An abnormality is detected based on an image captured by a camera 21a mounted on a first moving body 20a. For example, the first moving body 20a detects the abnormality, and transmits a notice of the abnormality detection and the position information of the first moving body 20a at the time of the abnormality detection to the management system 30. As another example, the first moving body 20a may transmit the image and the position information to the management system 30, the management system 30 may detect the abnormality based on the image, and the management system 30 may identify the position information of the first moving body 20a at the time of the abnormality detection. The position of the first moving body 20a at the time of the abnormality detection is hereinafter referred to as a “abnormality detection position.”

The management system 30 acquires the position information of the terminal 11i from the terminal 11i of the security guard 10i. The position information of the terminal 11i is regarded as position information of the security guard 10i. Based on the position information of the security guards 10i, the management system 30 selects one or more first security guards 10a relatively close to the abnormality detection position. For example, the first security guard 10a is a security guard 10 who is present within a predetermined range from the abnormality detection position (i.e., the position of the first moving body 20a). As another example, the first security guard 10a may be a security guard 10 closest to the abnormality detection position (i.e., the position of the first moving body 20a).

The management system 30 notifies the selected first security guard 10a of the abnormality detection position (i.e., the position of the first moving body 20a). More specifically, the management system 30 transmits information of the abnormality detection position to a terminal 11a of the selected first security guard 10a. The terminal 11a displays the information of the abnormality detection position on a display. The first security guard 10a recognizes the abnormality detection position. Then, the first security guard 10a rushes (harries) to the abnormality detection position. In this manner, the security is implemented by the cooperation of the one or more security guards 10 and the one or more moving bodies 20.

### 2. Security Simulation

According to the present embodiment, a simulation of the security system is performed in order to search for and examine an appropriate security system. In particular, the simulation is performed in order to appropriately determine the position Xi(t) of the security guard 10i. It is a security simulation system 100 that performs such the simulation.

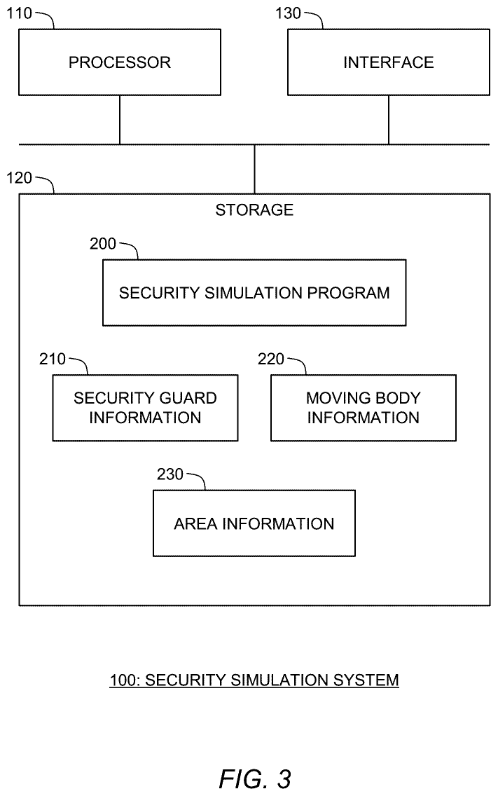

FIG. 3 is a block diagram showing an example of a configuration of the security simulation system 100 according to the present embodiment. The security simulation system 100 includes one or more processors 110 (hereinafter, simply referred to as a “processor 110” or “processing circuitry”), one or more storages 120 (hereinafter, simply referred to as a “storage 120”), and an interface 130. The processor 110 executes a variety of processing. For example, the processor 110 includes a central processing unit (CPU). The storage 120 stores a variety of information necessary for the processing. Examples of the storage 120 include a hard disk drive (HDD), a solid state drive (SSD), a volatile memory, a non-volatile memory, and the like. The interface 130 includes a network interface and a user interface. Examples of the user interface include a display device, a touch panel, a keyboard, a button, and the like.

A security simulation program 200 is a computer program for performing the simulation of the security system. The security simulation program 200 is stored in the storage 120. The security simulation program 200 may be recorded on a non-transitory computer-readable recording medium. The security simulation program 200 is executed by the processor 110. The functions of the security simulation system 100 may be implemented by a cooperation of the processor 110 executing the security simulation program 200 and the storage 120.

The storage 120 further stores security guard information 210, moving body information 220, and area information 230.

The security guard information 210 includes the total number N of the security guards 10. The total number N of the security guards 10 may be a predetermined value. In addition, the security guard information 210 includes the time dependent position Xi(t) of each security guard 10i. The simulation is performed in order to appropriately determine the position Xi(t) of each security guard 10i. That is, the position Xi(t) of each security guard 10i is a “variable” in the simulation according to the present embodiment. For example, a large number of patterns of the positions Xi(t) are prepared in advance, and an optimum pattern is selected from the large number of patterns of the positions Xi(t) through the simulation.

The moving body information 220 includes the total number M of the moving bodies 20. The total number M of the moving bodies 20 may be a predetermined value. In addition, the moving body information 220 includes the time-dependent position Kj(t) of each moving body 20j. The position Kj(t) of each moving body 20j is predetermined. That is to say, a route plan of each moving body 20j is determined in advance. The moving body information 220 further includes performance information of each moving body 20j. Examples of the performance of each moving body 20j include an installation position, an orientation, an angle of view, a photographable range, and the like of the camera 21j.

The area information 230 is information about the predetermined area. The area information 230 includes area configuration information indicating a configuration (arrangement) of stationary objects (for example, buildings, roads, and the like) that constitute the predetermined area. In addition, the area information 230 includes human/mobility information regarding humans and mobilities (for example, vehicles and robots) in the predetermined area. The human/mobility information may be actual data in the past, may be quasi-real-time data, or may be predicted data. Moreover, the area information 230 may include abnormality occurrence information regarding occurrence of the abnormality in the predetermined area. The abnormality occurrence information may be actual data in the past or may be prediction data. The abnormality occurrence information may give an arbitrary abnormality occurrence pattern.

The security guard information 210, the moving body information 220, and the area information 230 are provided through the interface 130.

The processor 110 performs a simulation of the predetermined area based on the security guard information 210, the moving body information 220, and the area information 230. For example, a DigitalTwin technology is used for the simulation. The simulation of the predetermined area includes simulations of the N security guards 10, the M moving bodies 20, humans, mobilities, abnormality occurrences, and the like in the predetermined area. Each security guard 10i moves according to the time-dependent position Xi(t), and each moving body 20j moves according to the time-dependent position Kj(t).

As described in FIG. 2, when an abnormality is detected based on the camera 21a mounted on the first moving body 20a, the first security guard 10a rushes to the abnormality detection position (i.e., the position of the first moving body 20a). For example, the first security guard 10a is a security guard 10 who is present within a predetermined distance from the abnormality detection position. As another example, the first security guard 10a may be a security guard 10 closest to the abnormality detection position. A time required for the first security guard 10a to rush to the abnormality detection position is hereinafter referred to as a “rushing time RUT.” It can also be said that the rushing time RUT is a time from when the abnormality is detected to when the first security guard 10a arrives at the abnormality detection position. The rushing time RUT depends on the position Xi(t) of the security guard 10i and the position Kj(t) of the moving body 20j. In the simulation, the processor 110 calculates the rushing time RUT.

An area that can be monitored by the N security guards 10 and the M moving bodies 20 in a predetermined period of time is hereinafter referred to as a “security coverage area CVR.” The predetermined period of time is, for example, one day. The security coverage area CVR also depends on the position Xi(t) of the security guard 10i and the position Kj(t) of the moving body 20j. When the N security guards 10 and the M moving bodies 20 move in a distributed manner, the security coverage area CVR becomes wide. Conversely, when the N security guards 10 and the M moving bodies 20 move in the same place in an overlapping manner, the security coverage area CVR becomes narrow. In the simulation, the processor 110 calculates the security coverage area CVR.

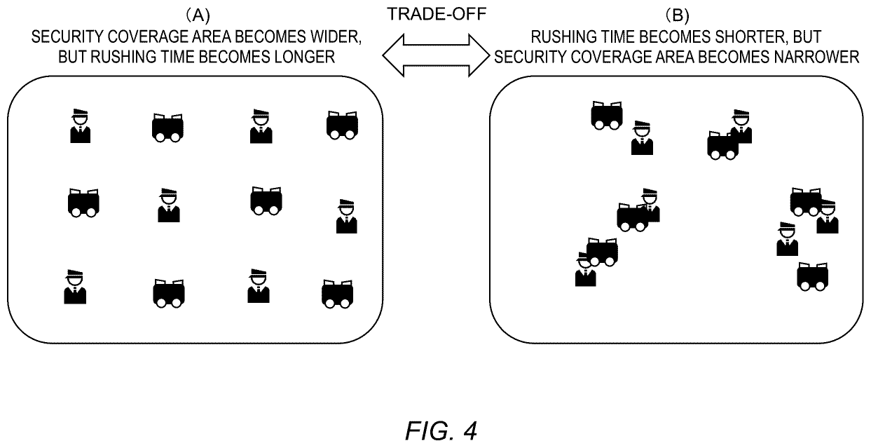

According to the present embodiment, the above-described two parameters “rushing time RUT” and “security coverage area CVR” are evaluated in order to appropriately determine the position Xi(t) of each security guard 10i. That is to say, the position Xi(t) of each security guard 10i is determined in consideration of the rushing time RUT and the security coverage area CVR. As shown in FIG. 4, the rushing time RUT and the security coverage area CVR are in a trade-off relationship.

When the security guards 10 and the moving bodies 20 are dispersed and move along largely different routes, the security coverage area CVR becomes wider. However, since the security guard 10 and the moving body 20 are away from each other, the rushing time RUT at the time of the abnormality detection becomes longer.

On the other hand, when the security guards 10 and the moving bodies 20 are clustered and move along similar routes, the security coverage area CVR becomes narrower. However, since the security guard 10 is present near the moving body 20, the rushing time RUT at the time of the abnormality detection becomes shorter.

As an evaluation function based on the “rushing time RUT” and the “security coverage area CVR” which are in the trade-off relationship, the following one is used.

### <Evaluation Function>

F(Xi(t))=α×f1(Xi(t))+β×f2(Xi(t))

A first function f1(Xi(t)) is a function representing the reciprocal of the rushing time RUT. A value of the first function f1(Xi(t)) increases as the rushing time RUT becomes shorter. Since the position Kj(t) of the moving body 20j is predetermined, the first function f1(Xi(t)) is a function of the position Xi(t) of the security guard 10i. A second function f2(Xi(t)) is a function representing a size of the security coverage area CVR. A value of the second function f2(Xi(t)) increases as the security coverage area CVR becomes wider. Since the position Kj(t) of the moving body 20j is predetermined, the second function f2(Xi(t)) is a function of the position Xi(t) of the security guard 10i.

A first weight α is a weight given to the rushing time RUT, and is multiplied by the first function f1(Xi(t)). On the other hand, a second weight β is a weight given to the security coverage area CVR, and is multiplied by the second function f2(Xi(t)). The first weight α is set to a value larger than 0 and smaller than 1 (0<α<1). Similarly, the second weight β is set to a value larger than 0 and smaller than 1 (0<β<1). Further, the first weight α and the second weight β are contrary to each other, and the second weight β decreases as the first weight α increases. For example, the first weight α and the second weight β have a relationship of β=1-a. The first weight α and the second weight β may be designated by a user of the simulation.

As described above, the evaluation function F (Xi(t)) is defined based on the rushing time RUT and the security coverage area CVR which are in the trade-off relationship. The value of the evaluation function F (Xi(t)) increases as the rushing time RUT becomes shorter and as the security coverage area CVR becomes wider.

The processor 110 performs the simulation while variously changing the pattern of the position Xi(t) of each security guard 10i, and calculates the value of the evaluation function F (Xi(t)) for each pattern. For example, a predetermined number of patterns of the positions Xi(t) are prepared in advance, and the processor 110 performs the simulation for each pattern to calculate the value of the evaluation function F (Xi(t)) for each pattern. Then, the processor 110 determines the position Xi(t) of each security guard 10i such that the value of the evaluation function F (Xi(t)) becomes equal to or higher than a predetermined level. The processor 110 may determine the position Xi(t) of each security guard 10i so as to maximize the value of the evaluation function F (Xi(t)). That is, the processor 110 may select the position Xi(t) of each security guard 10i at which the value of the evaluation function F (Xi(t)) is maximized, as the optimal pattern.

The processor 110 presents information on the determined position Xi(t) of each security guard 10i to a user of the simulation through the interface 130. For example, the processor 110 displays the information on the determined position Xi(t) of each security guard 10i on the display device.

### 3. Effects

As described above, according to the present embodiment, the simulation of the security system that is based on the cooperation of one or more security guards 10 and one or more moving bodies 20 is performed. In the simulation, the rushing time RUT and the security coverage area CVR, which are in a trade-off relationship, are taken into consideration. More specifically, the value of the evaluation function F (Xi(t)), which increases as the rushing time RUT becomes shorter and as the security coverage area CVR becomes wider, is calculated. Then, the position Xi(t) of each security guard 10i is determined such that the value of the evaluation function F (Xi(t)) becomes equal to or higher than a predetermined level. In this manner, it is possible to search for and examine an appropriate security system. This also contributes to proper labor costs of the security guards 10.

What is claimed is:

1. A security simulation system for performing a simulation of a security system, the security system in a predetermined area being based on a cooperation of N security guards (N is an integer of 1 or more) and M moving bodies (M is an integer of 1 or more), wherein a time-dependent position of each of the N security guards is a variable in the simulation, and a time-dependent position of each of the M moving bodies is predetermined,
the security simulation system comprising processing circuitry configured to:
perform simulations of the N security guards, the M moving bodies, and abnormality occurrence in the predetermined area;
calculate a rushing time from when an abnormality is detected based on a camera mounted on a first moving body to when a first security guard arrives at a position of the first moving body;
calculate a security coverage area that can be monitored by the N security guards and the M moving bodies in a predetermined period of time; and
determine the time-dependent position of each of the N security guards such that a value of an evaluation function becomes equal to or higher than a predetermined level, wherein the evaluation function increases as the rushing time becomes shorter, and the evaluation function increases as the security coverage area becomes wider.

2. The security simulation system according to claim 1, wherein
the first security guard is a security guard closest to the first moving body.

3. The security simulation system according to claim 1, wherein
the processing circuitry is configured to determine the time-dependent position of each of the N security guards such that the value of the evaluation function is maximized.

4. The security simulation system according to claim 1, wherein
in the evaluation function, a first weight is given to the rushing time, a second weight is given to the security coverage area, and
the second weight decreases as the first weight increases.

5. A non-transitory computer-readable recording medium storing a security simulation program for performing a simulation of a security system, the security system in a predetermined area being based on a cooperation of N security guards (N is an integer of 1 or more) and M moving bodies (M is an integer of 1 or more), wherein a time-dependent position of each of the N security guards is a variable in the simulation, and a time-dependent position of each of the M moving bodies is predetermined, the security simulation program, when executed by a computer, causing the computer to execute:
performing simulations of the N security guards, the M moving bodies, and abnormality occurrence in the predetermined area;
calculating a rushing time from when an abnormality is detected based on a camera mounted on a first moving body to when a first security guard arrives at a position of the first moving body;
calculating a security coverage area that can be monitored by the N security guards and the M moving bodies in a predetermined period of time; and
determining the time-dependent position of each of the N security guards such that a value of an evaluation function becomes equal to or higher than a predetermined level, wherein the evaluation function increases as the rushing time becomes shorter, and the evaluation function increases as the security coverage area becomes wider.
